(19) United States
(12) Patent Application Publication
(10) Pub. No.: US 2016/0380196 A1
(43) Pub. Date: Dec. 29, 2016

(54) BROADBAND PHOTORESISTOR

(71) Applicant: YISSUM RESEARCH DEVELOPMENT COMPANY OF THE HEBREW UNIVERSITY OF JERUSALEM LTD., Jerusalem (IL)

(72) Inventors: Ido EISENBERG, Jerusalem (IL); Yosef PALTIEL, Mazkeret Batya (IL); Shira YOCHELIS, Ness Ziona (IL)

(21) Appl. No.: 15/121,070

(22) PCT Filed: Feb. 27, 2015
(86) PCT No.: PCT/IL2015/050220

§ 371 Date: Aug. 24, 2016

Related U.S. Application Data
(60) Provisional application No. 61/945,307, filed on Feb. 27, 2014.

(51) Int. Cl. H01L 51/00; H01L 51/42

(52) U.S. Cl. CPC H01L 51/005; H01L 51/42; H01L 2031/0344

(57) ABSTRACT

A photoresistor comprising: a semiconductor substrate selected from Gallium-Nitride, Gallium-Arsenic, Gallium Phosphide, and Aluminum Gallium Nitride, or any combination thereof; a layer of organic molecules that is disposed on at least a portion of the surface of the semiconductor substrate; and two conductors in contact with the layer of organic molecules.

### FIELD OF THE INVENTION

The invention relates to the field of photodectectors.

### BACKGROUND

Photoresistors, sometimes referred to as light-dependent resistors (LDRs), typically include a high-resistance semiconductor layer that is sensitive to high photonic frequencies. When incident light hits the surface of such resistors, bound electrons absorb the light and are excited into a higher state, transforming the semiconductor to a conductive state. Doping the semiconductor, such as by adding compounds or impurities, may increase the conductivity of photoresistors.

The foregoing examples of the related art and limitations related therewith are intended to be illustrative and not exclusive. Other limitations of the related art will become apparent to those of skill in the art upon a reading of the specification and a study of the figures.

### SUMMARY

The following embodiments and aspects thereof are described and illustrated in conjunction with systems, tools and methods which are meant to be exemplary and illustrative, not limiting in scope.

There is provided, in accordance with an embodiment, a photoresistor comprising: a semiconductor substrate comprising a Group III-V material selected from the group consisting of: InAs, InP, InN, GaN, InSb, InAsP, InGaAs, GaAs, GaP, GaSb, AlP, AlN, AlAs, AlSb, CdSeTe and ZnCdSe; a layer of organic molecules that is disposed on at least a portion of the surface of the semiconductor substrate; and two contacts in contact with the layer of organic molecules.

In some embodiments, the organic molecules comprise one or more groups selected from one or more thiols (—SH) and/or amines (—NH2).

In some embodiments, the organic molecules comprising one or more thiol groups are alkyls.

In some embodiments, the organic molecules are selected from the group consisting of: 1,9-nonanedithiol (NDT) and cysteamine (CYS).

In some embodiments, the semiconductor substrate is selected from the group consisting of: Gallium-Nitride, Gallium-Arsenic, Gallium Phosphide, and Aluminum Gallium Nitride.

In some embodiments, the two contacts form an interdigital pattern on the surface of the semiconductor substrate.

There is provided, in accordance with an embodiment, a method for detecting light, the method comprising (a) illuminating, with ultraviolet light, a photoresistor comprising a layer of organic molecules, wherein the illuminating light has an intensity that is insufficient for saturating the photoresistor; (b) measuring a response of the photoresistor to the illumination of step (a).

In some embodiments, the method further comprises repeating steps (a) and (b) at a frequency that is less than or equal to 2 Hertz.

In some embodiments, the photoresistor comprises a semiconductor substrate selected from the group consisting of: Gallium-Nitride, Gallium-Arsenic, Gallium Phosphide, and Aluminum Gallium Nitride, and wherein the layer of organic molecules, are selected from the group consisting of: 1,9-nonanedithiol (NDT) and cysteamine (CYS).

There is provided, in accordance with an embodiment, a method for detecting light, the method comprising: (a) illuminating, with ultraviolet light, a photoresistor comprising a layer of organic molecules; (b) substantially saturating the photoresistor with the illuminating ultraviolet light; (c) illuminating the saturated photoresistor with light in the visible and/or near-infrared wavelengths; and (d) measuring a response of the photoresistor to the illumination of light in the visible and/or near-infrared wavelengths.

In some embodiments, the photoresistor comprises a semiconductor substrate selected from the group consisting of: Gallium-Nitride, Gallium-Arsenic, Gallium Phosphide, and Aluminum Gallium Nitride, and wherein the layer of organic molecules, are selected from the group consisting of: 1,9-nonanedithiol (NDT) and cysteamine (CYS).

There is provided, in accordance with an embodiment, a method for manufacturing a photoresistor, the method comprising: subjecting a semiconductor substrate layer to a pre-treatment to remove contaminations; and adsorbing a layer of organic molecules on at least a portion of the treated substrate layer.

In some embodiments, the method further comprises depositing two contacts on the substrate layer, and annealing the substrate layer with the deposited conductors.

In some embodiments, the method further comprises cleaning at least one surface of the semiconductor substrate layer.

In some embodiments, the semiconductor substrate comprises one or more Group III-V material, being selected from InAs, InP, InN, GaN, InSb, InAsP, InGaAs, GaAs, GaP, GaSb, AlP, AlN, AlAs, AlSb, CdSeTe, ZnCdSe and any combination thereof.

In some embodiments, the semiconductor substrate is the group consisting of: Gallium-Nitride, Gallium-Arsenic, Gallium Phosphide, and Aluminum Gallium Nitride.

In some embodiments, the pre-treatment comprises any of etching, heating, putting under vacuum, irradiating, removing native oxide layer, forming hydrogen-terminated surface, exposure to hydrogen gas, sonication, UV/Ozon treatment, plasma asher treatment, Piranha treatment, Hydrogen Fluoride, Hydrogen Chloride, or Ammonia cleaning treatment, solution treatment, or any combination thereof.

In some embodiments, the organic molecules comprise one or more groups selected from one or more thiols (—SH) and/or amines (—NH2).

In some embodiments, the molecules comprising one or more thiol groups are alkyls.

In some embodiments, the organic molecules are selected from 1,9-nonanedithiol (NDT) and cysteamine (CYS).

In addition to the exemplary aspects and embodiments described above, further aspects and embodiments will become apparent by reference to the figures and by study of the following detailed description.

### BRIEF DESCRIPTION OF THE FIGURES

Exemplary embodiments are illustrated in referenced figures. Dimensions of components and features shown in the figures are generally chosen for convenience and clarity of presentation and are not necessarily shown to scale. The figures are listed below.

FIG. 1A illustrates a top view of a photoresistor, in accordance with an embodiment;

FIG. 1B illustrates a cross-sectional view of the photoresistor of FIG. 1A, in accordance with an embodiment;

FIG. 1C illustrates a cross-sectional view of the photoresistor of FIG. 1A, in accordance with another embodiment;

FIGS. 2A-J illustrate experimental results for measuring the photo response of a number of exemplary photoresistors, in accordance with some embodiments;

FIGS. 3A-B show response time of a photoresistor, in accordance with an embodiment;

FIGS. 4A-B show two spectral response graphs of exemplary photoresistors having Nonanedithiol (NDT) and Cysteamine (CYS) layers, respectively, in accordance with some embodiments; and

FIG. 5 shows a typical normalized time response for an illuminated photoresistor.

### DETAILED DESCRIPTION

A photoresistor and methods for fabricating and operating the same are disclosed herein. These enable broadband sensitivity of the photoresistor, and improve its response and recovery times by pre-treating the surface of a semiconductor substrate to remove contaminants, and/or by depositing a layer of organic molecules on at least a portion of the surface of the substrate. The surface, thus treated and coated, may exhibit a response to a relatively broad spectral range of light, spanning from the near infrared (NIR), through visible (VIS) and to ultraviolet (UV) frequencies.

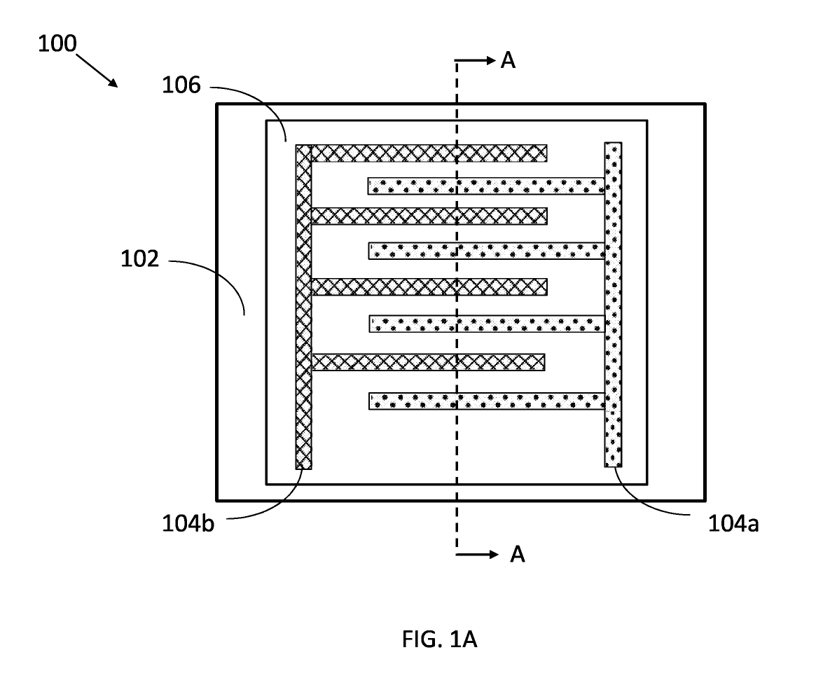

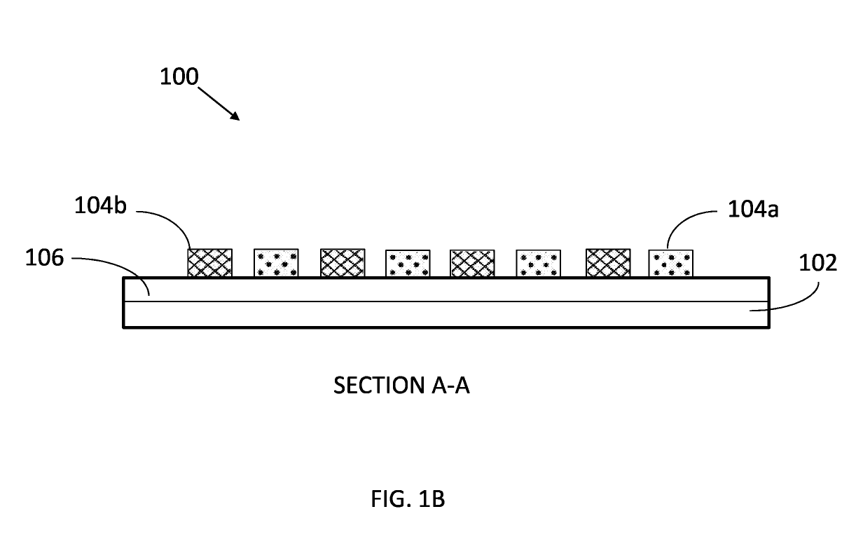

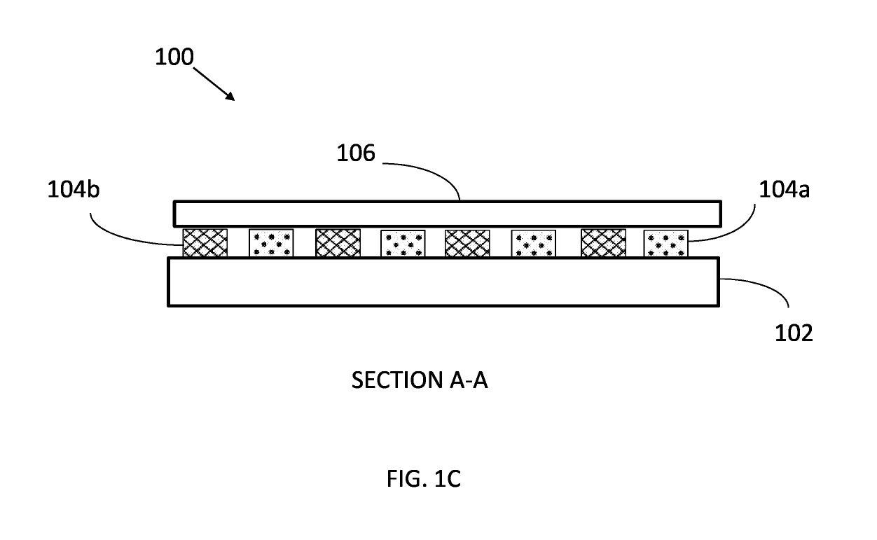

Reference is now made to FIG. 1A, which illustrates a top view of a photoresistor 100, and to FIGS. 1B-C, which illustrate two embodiments of a cross-section of that photoresistor.

Photoresistor 100 may include a semiconductor substrate 102 provided with at least two electrical contacts 104a and 104b for connecting to a voltage supply (not shown). A layer 106 of organic molecules may be disposed on at least a portion of the surface of substrate 102. Contacts 104a and 104b may have contact with layer 106.

For illustrative purposes only, FIGS. 1A-B shows contacts 104a and 104b positioned above layer 106, which is positioned above substrate 102. However, in another embodiment, as shown in FIG. 1C, layer 106 may be positioned above contacts 104a and 104b, which may be positioned above substrate 102.

In an embodiment, conductors 104a and 104b may each be a layer of a suitable metal. In an embodiment, conductors 104a and 104b may form an interdigital pattern on the surface of the substrate 102 to increase the effective area of detector 100. For example, the conductors may be Chromium/Gold (Cr/Au) contacts with a thickness of 10/100 nanometers (nm), respectively.

Conductors 104a and 104b are shown with different hatching patterns for illustrative purposes only, and are to be understood as being comprised of the same conductive material or of materials with compatible conductive properties. For example, conductor 104a, shown with a dotted pattern, may be connected to a first potential, and conductor 104b, shown with a cross-hatch pattern, may be connected to a second potential that is lower than the first potential. A current meter (not shown) may be connected to conductor 104b to measure the resistivity of device 100. The illumination of device 100 may increase the conductivity of substrate 102 disposed with layer 106. Substrate 102 and layer 106 may thus create a conductive bridge between conductors 104a and 104b, allowing a current to pass through photoresistor 100. The level of current may be measured to determine a conductive property of photoresistor 100, corresponding to the wavelength of the illumination signal.

In some embodiments, substrate 102 may comprise an element of Group IIIB, IVB, VB, VIB, VIIB, VIIIB, IB, IIB, IIIA, IVA or VA of block d of the Periodic Table of the Elements.

In some embodiments, substrate 102 may comprise a transition metal selected from Group IIIB, IVB, VB, VIB, VIIB, VIIIB, IB or IIB of block d of the Periodic Table.

In some embodiments, substrate 102 may comprise a Group III-V material, being selected from InAs, InP, InN, GaN, InSb, InAsP, InGaAs, GaAs, GaP, GaSb, AlP, AlN, AlAs, AlSb, CdSeTe, ZnCdSe or any combination thereof.

In an exemplary embodiment, substrate 102 is made from any of Gallium-Nitride (GaN) or Gallium-Arsenic (GaAs), Gallium phosphide (GaP), Aluminum Gallium Nitride (AlGaN) or a combination thereof.

In some embodiments, substrate 102 may be at least partially coated with layer 106 of organic molecules. In some embodiments, a region of the surface of substrate 102 may remain untreated, and another region may be reinforced with a coating of only the organic molecules.

The terms “coating”, “film” and “layer” are used interchangeably and refer to a coating applied to all or part of the surface of the semiconductor material. The layer may be continuous or discontinuous.

The formation of the layer of the organic material on the surface of the semiconductor material may be achieved by any method known in the art. In a typical preparation protocol, the organic material is provided in a solution, emulsion, ink, or a mixture thereof. Subsequently, the organic layer is formed by a physical or chemical method such as deposition (e.g., immersing the semiconductor material in a solution comprising the organic molecular entities), printing, jet printing, differential roll printing, contact printing, coating, spin coating, or any combination thereof, or any other technique enabling such a contact.

Layer 106 of the organic material may be a monolayer, a bi-layer, a multi-layer, a thin film, a molecular layer or any form of assembly of the organic molecules blend. Thus, a layer of the organic material incorporates all desired material components which endow the multilayer products of the invention with the desired optical and/or mechanical properties.

In some embodiments, the thickness of layer 106 may be between 1 to 1000 nm, or from 5 and 100 nm, or from 5 and 50 nm, or from 5 and 30 nm, or from 5 and 20 nm, or from 50 to 900 nm, or from 100 to 700 nm, or from 200 to 500 nm.

In some embodiments, the concentration of the organic molecules in organic layer 106 is e.g., at least 10⁵, at least 10⁶, at least 10⁷, at least 10⁸, at least 10⁹, at least 10¹⁰, at least 10¹¹, at least 10¹², at least 10¹³, at least 10¹⁴, at least 10¹⁵, at least 10¹⁶, at least 10¹⁷, at least 10¹⁸, at least 10¹⁹, or at least 10²⁰ molecules per cm².

It should be noted that a monolayer or a multilayer coating may comprise one or more organic materials, as described hereinbelow.

Thus, the number and identity of each of the organic molecule layers is variable and may depend on the desired properties as well as on the desired film thickness, which may be controlled using, e.g., different spreading or coating methods.

In some embodiments, the multilayer comprises two or more layers (2, 3, 4, 5, 6, 7, 8, 9, 10 or more) of the organic materials.

The organic coating may be instantly formed (e.g., solidified) or may require further treatment steps such as heating, irradiation, drying, vacuuming or any combination thereof.

In some embodiments, the organic material comprises a plurality of molecules that belong to one or more thiol (—SH) and/or amine (—NH₂) groups.

In some embodiments, the molecules comprising one or more thiol groups are alkyls.

As used herein, the term “alkyl” may describe an aliphatic hydrocarbon including straight chain and branched chain groups. Optionally, the alkyl group may have 21 to 100 carbon atoms, or, alternatively, 21-50 carbon atoms. Whenever a numerical range, e.g., “21-100”, is stated herein, it may imply that the group, in this case the alkyl group, may contain 21 carbon atoms, 22 carbon atoms, 23 carbon atoms, etc., up to and including 100 carbon atoms. In the context of the present invention, a “long alkyl” may be an alkyl having at least 20 carbon atoms in its main chain (the longest path of continuous covalently attached atoms). A short alkyl therefore may have 20 or less main-chain carbons. The alkyl may be substituted or unsubstituted, as defined herein. When substituted, the substituent group may be, for example, cycloalkyl, alkenyl, alkynyl, aryl, heteroaryl, heteroalicyclic, halo, hydroxy, alkoxy, aryloxy, thiohydroxy, thioalkoxy, thioaryloxy, sulfinyl, sulfonyl, sulfonate, nitrile, nitro, azide, phosphonyl, phosphinyl, oxo, carbonyl, thiocarbonyl, urea, thiourea, carbamyl, N-carbamyl, O-thiocarbamyl, N-thiocarbamyl, C-amido, N-amido, C-carboxy, O-carboxy, sulfonamide, and amino, as these terms are defined herein.

The term “alkyl”, as used herein, also encompasses saturated or unsaturated hydrocarbon, hence this term further encompasses alkenyl and alkynyl.

The term “alkenyl” describes an unsaturated alkyl, as defined herein, having at least two carbon atoms and at least one carbon-carbon double bond. The alkenyl may be substituted or unsubstituted by one or more substituents, as described hereinabove.

The term “alkynyl”, as defined herein, is an unsaturated alkyl having at least two carbon atoms and at least one carbon-carbon triple bond. The alkynyl may be substituted or unsubstituted by one or more substituents, as described hereinabove.

The term “cycloalkyl” describes an all-carbon monocyclic or fused ring (i.e., rings which share an adjacent pair of carbon atoms) group where one or more of the rings does not have a completely conjugated pi-electron system. The cycloalkyl group may be substituted or unsubstituted, as indicated herein.

In exemplary embodiments, the organic molecules may be selected from 1,9-nonanedithiol (NDT) and cysteamine (CYS).

In some embodiments, prior to application of a coating onto the surface region of the semiconducting material, and depending on the nature of the semiconducting material, the surface region may be subjected to a pre-treatment to remove contaminations (e.g., chemisorbed or physisorbed organic and/or inorganic contaminants) therefrom, which pre-treatment may include etching, heating, putting under vacuum, irradiating, removing native oxide layer, forming hydrogen-terminated surface (surface hydrogenation), exposure to hydrogen gas, sonication, UV/Ozon treatment, plasma (e.g., ₂ plasma or Argon plasma) asher treatment, Piranha treatment, Hydrogen Fluoride (HF), Hydrogen Chloride (HCl) or Ammona (NH₃) cleaning treatment, solution treatment, or any combination thereof.

Reducing contaminants at the surface of the photoresistor may reduce the negative charge on the surface, and which may cause a reduction of the band bending and of the total surface resistance. Thus, pre-treating the semiconductor to remove contaminants may increase uniformity within the semiconductor and reduce its resistance variance.

A method for one mode of detecting light using the photoresistor of FIGS. 1A-B is now described, in accordance with an embodiment. The photoresistor may be connected to a voltage supply and a current meter, according to conventional methods. The photoresistor comprising a layer of organic molecules may be illuminated with UV light, such as by a UV lamp, or natural sunlight, where the UV light may have a relatively low intensity that is insufficient for saturating the photoresistor. For example, the intensity for the UV light may be up to approximately 10 microWatts/centimeter². The response of the photoresistor to the UV light may be measured, thereby detecting the UV light. The above steps may be repeated, such as at a frequency that is less than or equal to 2 Hertz.

A method for another mode of detecting light using the photoresistor of FIGS. 1A-B is now described, in accordance with an embodiment. The photoresistor may be connected to a voltage supply and a current meter, according to conventional methods. The photoresistor comprising a layer of organic molecules may be illuminated with a high intensity UV light source, such a a UV laser having an intensity greater than 1 microWatt/millimeter² (μW/mm²). The high intensity UV light may substantially saturate the device, such as by saturating the device within a saturation threshold. Thus saturated, the device may be illuminated by light in the VIS to NIR range. The response of the device to the light in the VIS to NIR range may be measured and analyzed, thereby detecting the light in the VIS to NIR range.

A method for manufacturing the photoresistor of FIGS. 1A-B is now described, in accordance with an embodiment. At least one surface of a semiconductor substrate layer, such as comprising any of the materials described herein, may be cleaned using conventional methods, such as by using acetone, ethanol, HF/HCl/NH4OH acids, Piranha treatment or any combination thereof. Two conductors may be deposited on the substrate layer using standard techniques, such as by evaporating the conducting material on the substrate layer using photolithography. The substrate with the conductors deposited thereon may be annealed, thereby allowing the produce to overcome the Schottky barrier and creating ohmic contact between the conductors and the substrate. For example, the substrate with the conductors may be annealed at 575° C. for 10 minutes. The surface of the annealed substrate layer may be modified, such as by treating it with plasma asher under argon, nitrogen, or oxygen flow, or alternatively by using any of the techniques described herein. A layer of organic molecules, such as any of the organic materials described herein may be adsorbed on at least a portion of the treated substrate layer.

### Exemplary Implementation and Experimental Results

In an experiment, GaN photoresistors samples were fabricated using a c-plane (0001) undoped GaN layer of approximately 2 micrometers (μm) thickness that was grown over a sapphire substrate wafer (by University Wafers, Inc.).

In a first stage, after the sample was cleaned with acetone and ethanol, Cr/Au alloy contacts of 10 and 100 nanometer (nm) thickness, respectively, were evaporated over the wafer using a standard lithography process. Then, the wafer was annealed at 575° C. for 10 minutes to overcome the Schottky barrier and to create ohmic contacts.

The wafer was diced into three chips, each of which contained five photoresistors. The chips were numbered 1, 2, and 3 and the photoresistors were denoted as a through e. Overall, 15 photoresistors were made.

In a second stage, the surface of each chip was treated by plasma asher. Chips 1 and 2 were cleaned by plasma under an argon flow and chip 3 was cleaned by plasma under an oxygen flow, each for a duration of 10 minutes.

In a third stage, a monolayer of organic molecules was adsorbed onto the sample's surface. The samples were washed by acetone and ethanol, dipped in hydrochloric acid (HCl) for 60 seconds, washed by distilled water, and then dipped in absolute ethanol for 3 hours. Then they were immersed overnight in 1 millimolar (mM) of the organic molecule solution, where chip 1 was dipped in 1,9-Nonanedithiol (NDT) in ethanol solution, and chips 2 and 3 were dipped in Cysteamine (CYS) in ethanol solution. This procedure was followed by ethanol cleaning and drying under nitrogen flow.

The electrical measurements of the photoresistors were performed by a probe station using a LabView program. A Keithley 2400 SourceMeter was used both for applying voltage and for measuring the resulting current. The integration time for the electrical measurements was 20 milliseconds (ms). The photoresistors were illuminated by UV using an Avantes AvaLight-DH-S-BAL deuterium light source through a 400 μm-diameter optic fiber. Illuminating at 532 nm and 980 nm was done by using an Altechna DPSS CW GREEN Laser and a Newport LQC980-220E laser, respectively, both in open air. The laser's power was 90 milliwatt (mW) and 40 mW for 532 nm and 980 nm, respectively, whereas the UV output power was approximately 5 microwatts (μW). For the spectral response measurements an incandescent light bulb with a range from 500 nm to 1350 nm was used. The light beam was illuminated through a slit of approximately 2 centimeters (cm), and then dispersed by a reflection grating, and collected by a collimating lens that coupled the light into a 600 μm-diameter optic fiber, and directed to the photoresistor's surface. For wavelengths above 900 nm or 1050 nm, low-pass filters of 700 nm and 1000 nm, respectively, were used to avoid second harmonics. The system's output spectrum was measured by Ocean Optics USB4000 for the VIS range and Ocean Optics NIRQuest 512 for the NIR range. The system's output power was measured by Ophir Orion PD for the low range and Thorlabs PDA10CS for the high range.

The current-voltage (I-V) curves of the photoresistors were measured and compared at three process stages: after annealing, after plasma asher treatment, and after adsorption of the organic molecules. Each measurement consisted of 10 I-V curves, corresponding to one curve every minute. The first curve was measured while the photoresistor was illuminated, and the other 9 subsequent curves were measured in the dark during a relaxation process. This process was repeated three times with three different light sources: a UV lamp, a 532 nm laser, and a 980 nm laser.

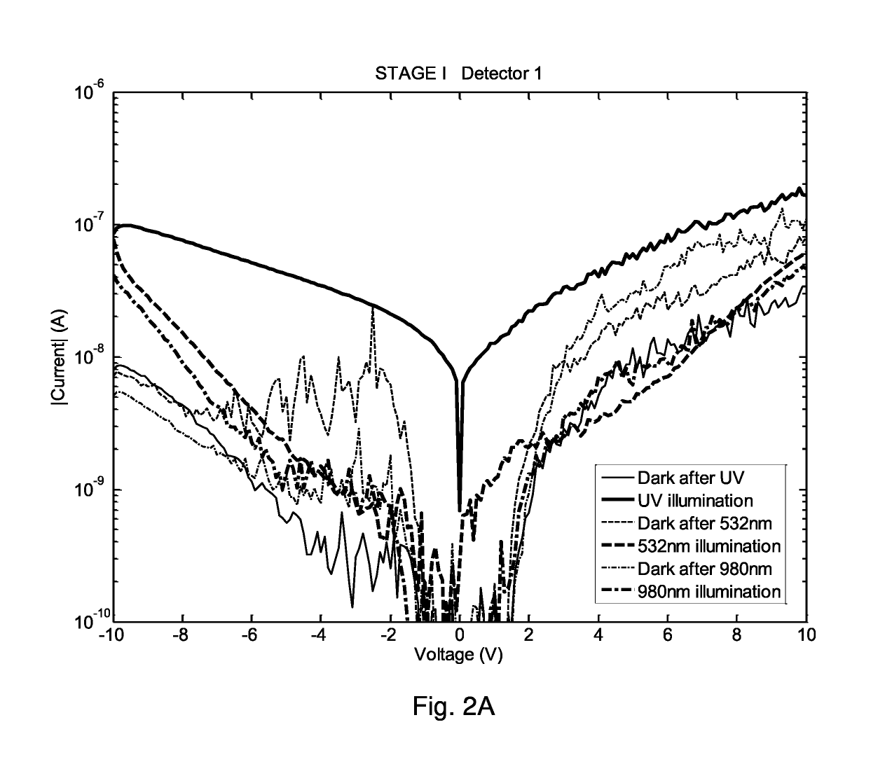

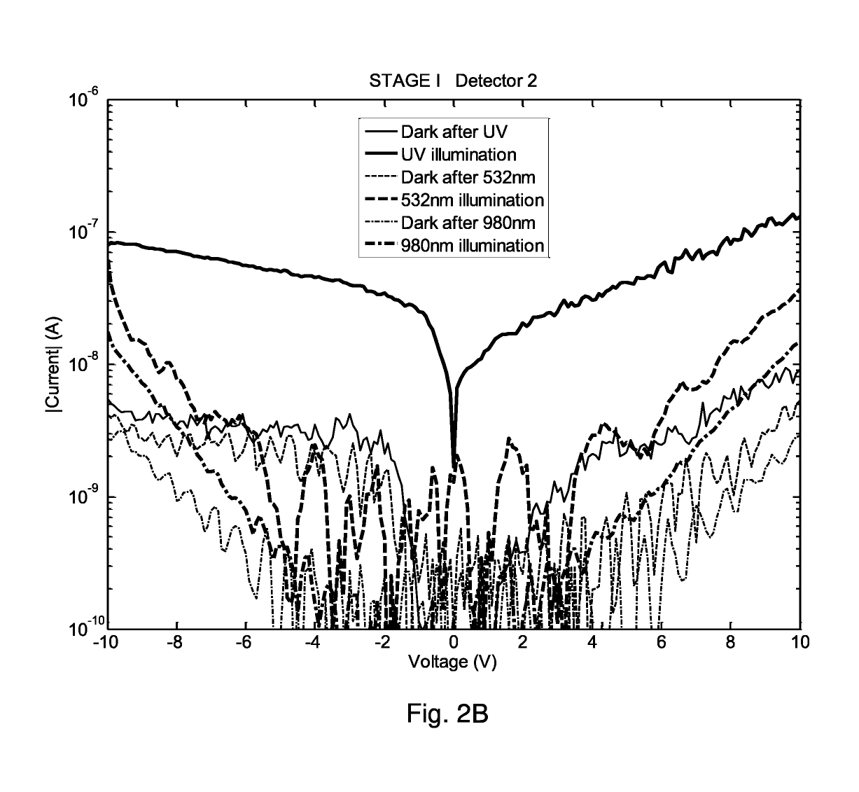

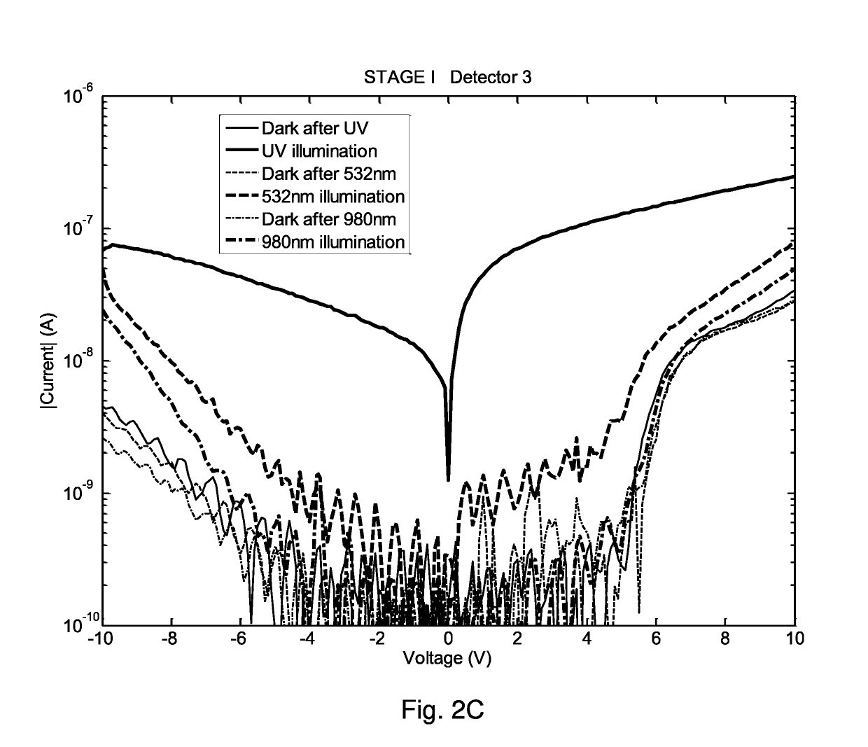

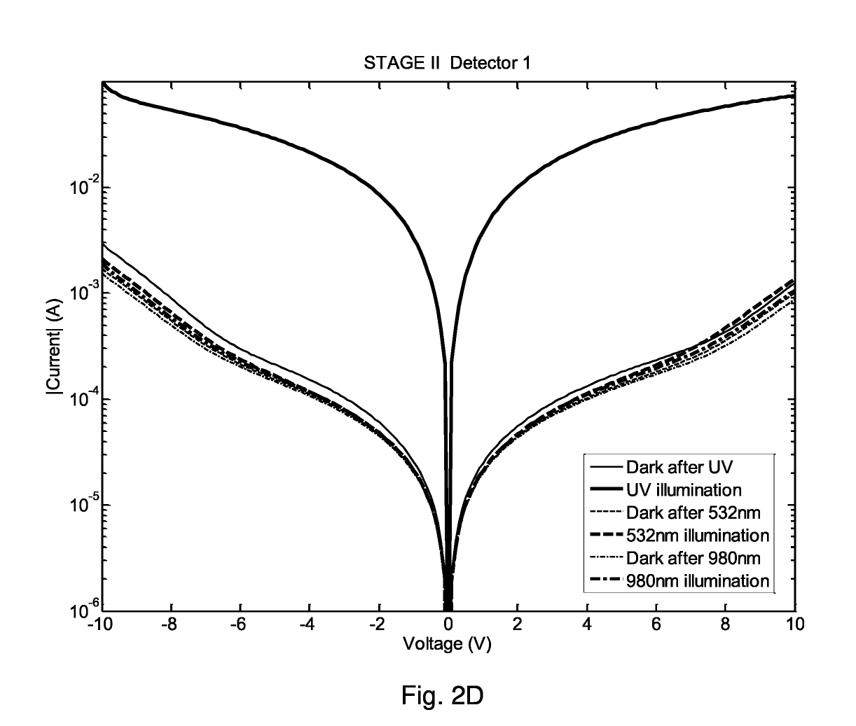

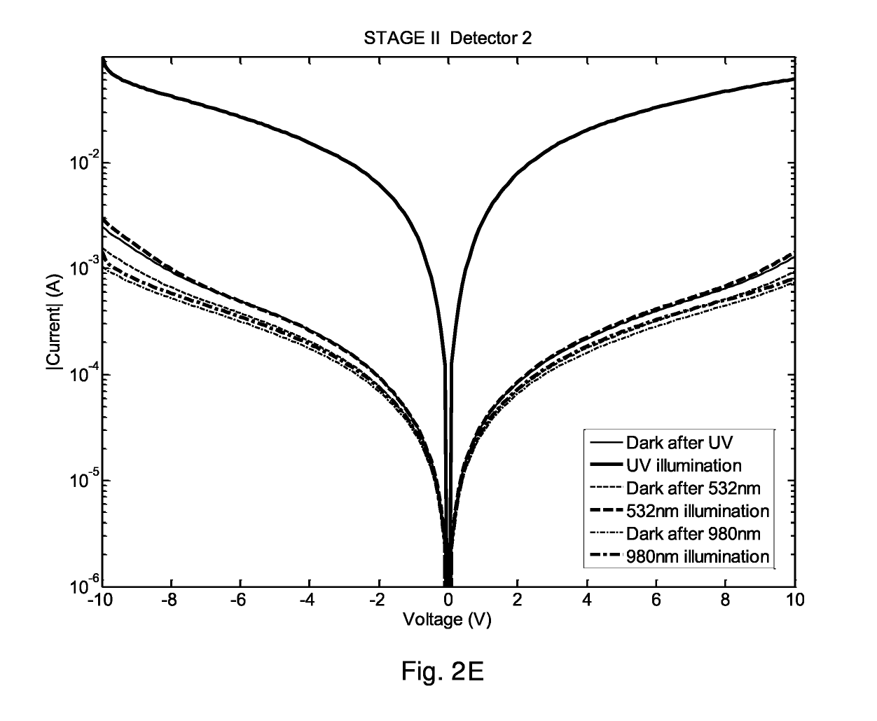

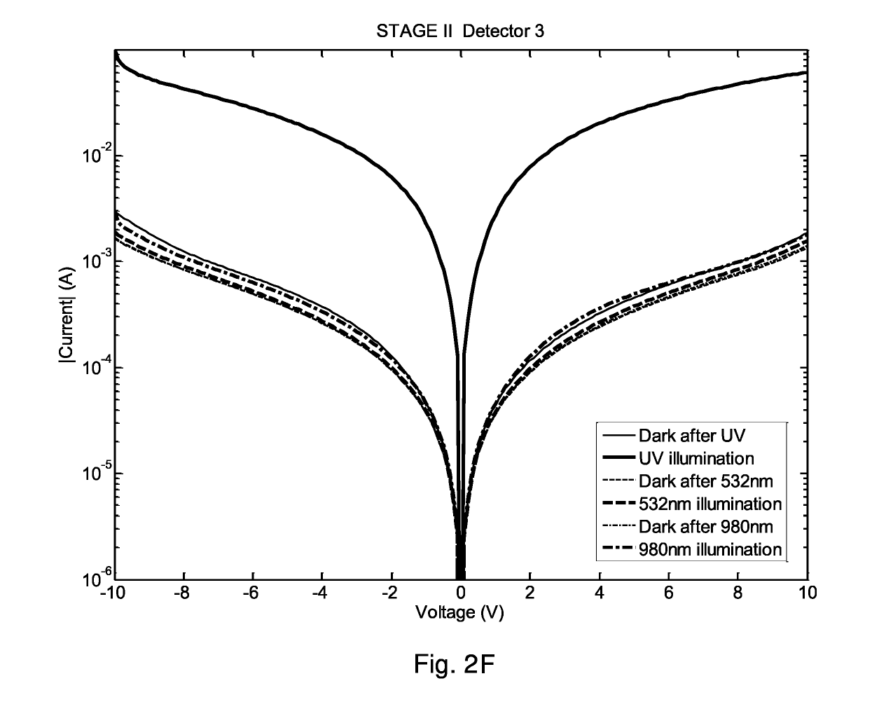

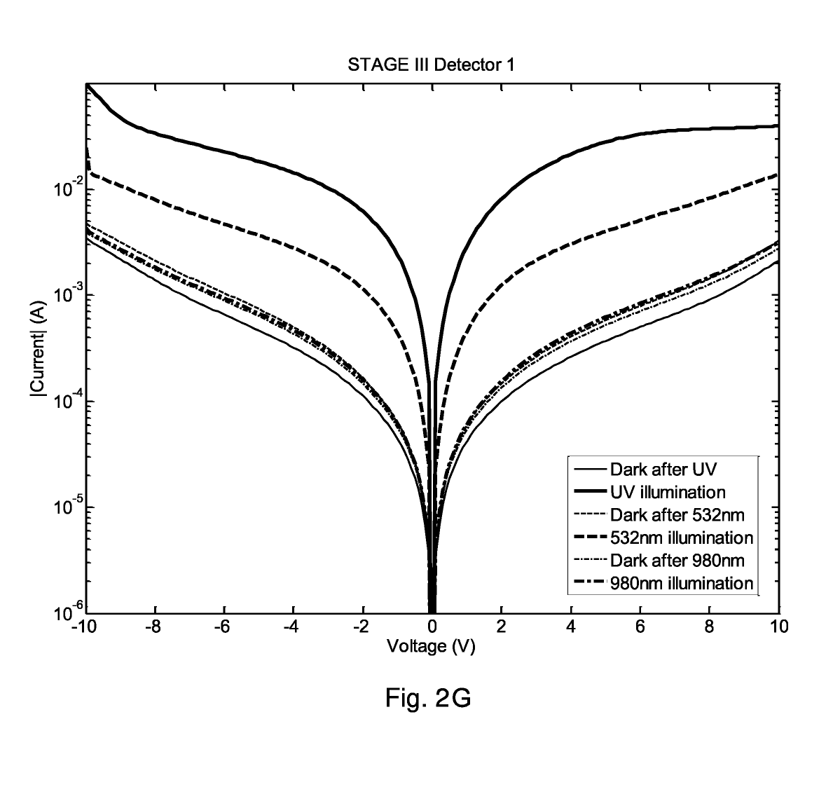

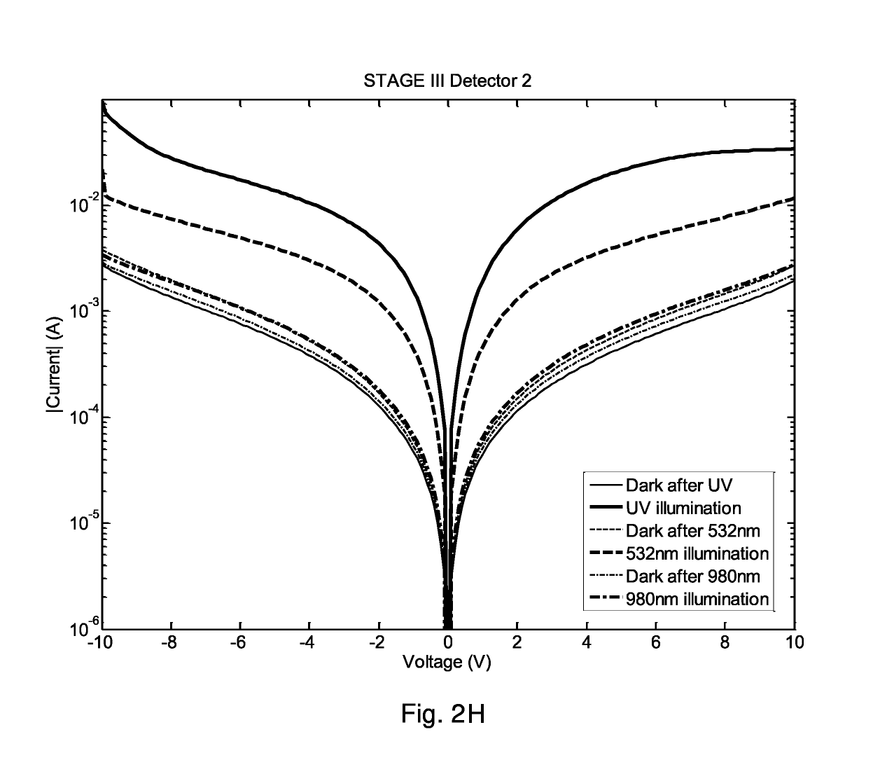

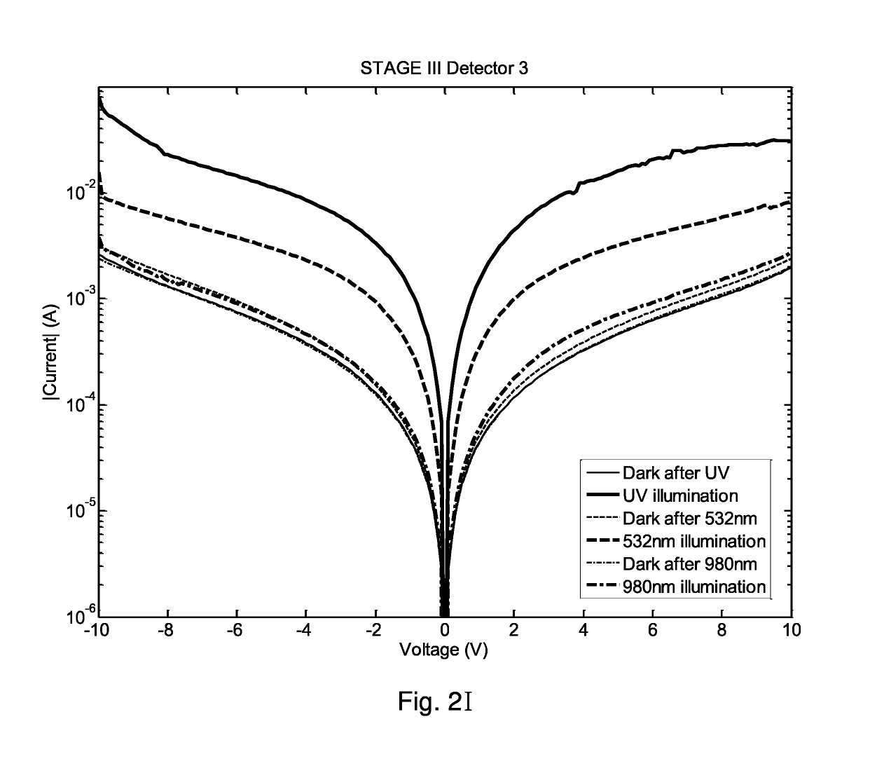

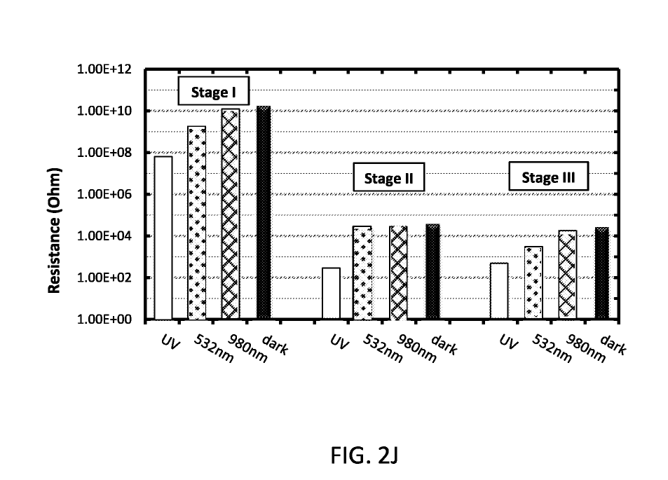

Reference is now made to FIGS. 2A-I, which illustrate the I-V curves of three photoresistors (1, 2 and 3) after annealing (stage I), after plasma asher treatment (stage II), and after adsorption of molecules (stage III).

At stage II, photoresistors 1 and 2 were treated by argon, whereas photoresistor 3 was by oxygen. At stage III, the NDT molecules were adsorbed to 1, whereas the CYS molecules were adsorbed to 2 and 3. The highest curve, shown as a solid black line, represents UV illumination, the dashed curve denotes the 532 nm illumination, and the dotted-dashed curve denotes the 980 nm illumination. The three lowest thin curves refer to the dark current.

The average resistance of the photoresistors at every stage is shown under illumination and in the dark at 2.1 V (FIG. 2J). A reduction in the photoresistors' resistance is observed at stage II after plasma asher treatment. The response to 532 nm may be reduced due to low resistance in the dark. At stage III, after adsorption of molecules, the responsivity to 532 nm improved, possibly owing to new surface energy levels. The results indicate a typical decrease in resistance of around five orders of magnitude and a reduction in the dark current variance by more than two orders of magnitude. Using both oxygen and an argon plasma asher, the current response to UV light was enhanced by approximately two orders of magnitude. At the third stage, which includes the adsorption of molecules, the responsivity to a 532 nm wavelength was improved for both NDT and CYS molecules.

FIG. 2J illustrates the average resistance of the photoresistors corresponding to each stage presented in FIGS. 2A-I.

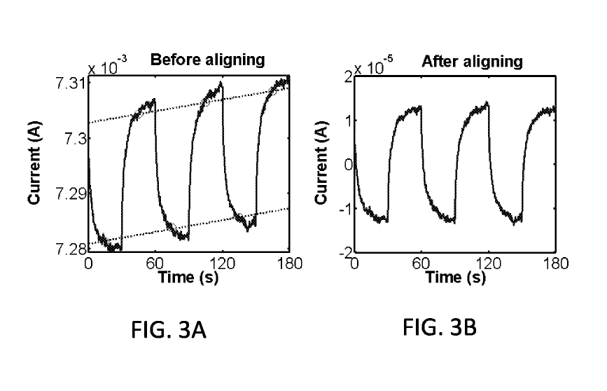

Reference is now made to FIG. 3A, which illustrates exemplary timed response behavior of the photoresistors of FIGS. 1A-B, in accordance with some embodiments.

To broaden the spectral range up to the NIR, the VIS-NIR light was measured while the photoresistor was illuminated by a UV light source. These time response measurements were taken at stage III (after the adsorption of molecules) for 3 minutes at 2.086 Volts (V), as follows:

a) The photoresistor was illuminated by a UV source for several minutes to stabilize the system,

b) The photoresistor was alternately illuminated at specific wavelengths for 30 seconds and left in the dark for 30 seconds (while UV source still works);

c) These steps were repeated three times for a total duration of 180 seconds. The spectral response measurements were performed 18 times in order to scan the wavelengths' response at the range of 500 nm to 1350 nm with 50 nm resolution. The excitation spectrum showed a typical band width of ˜50 nm. Sampling was done at ˜5 Hz.

FIG. 3A shows the time response at 900 nm for photoresistor 1, which was treated with plasma asher under argon flow and NDT molecules were adsorbed to its surface. The time response graph of FIG. 3A exhibits a response to an alternating current (AC) signal superimposed over a diagonal direct current (DC) signal. To improve the results, offset and drift were subtracted from the signal. The average of every 20 seconds from each 30 seconds segment, ignoring the first and last parts of the segment, was found and the linear fit of these three points (dotted lines) was calculated. The DC current offset was calculated as the average slope of these lines and their average current at t=90 seconds, to obtain the results without the offset, and which are shown in FIG. 3B.

To calculate the spectral response of the photoresistors, the above measurement of the total response was divided by the output power of the light source absorbed in the photoresistor area for each wavelength.

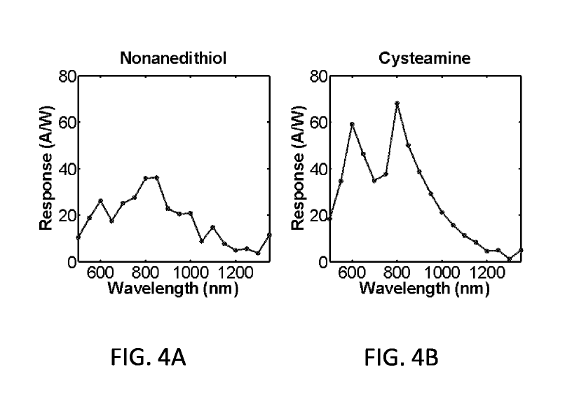

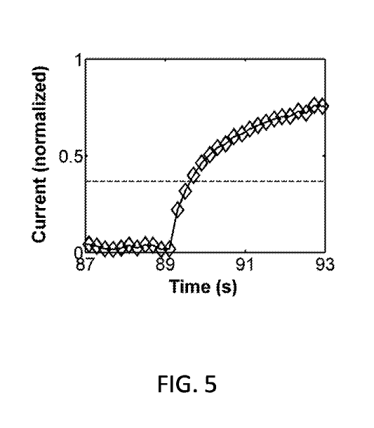

FIGS. 4A-B show the spectral response graphs for NDT and CYS, respectively. The photoresistors of the NDT and CYS molecules were averaged separately. FIGS. 4A-B show a substantial response from 10 to 70 Ampere/Watt (A/W) at the 600 nm to 1200 nm range. A peak in the response was measured for the NDT photoresistors at 800 nm, whereas the CYS photoresistors show two peaks, around 600 and 800 nm. In addition, the CYS photoresistors's response was higher than that of the NDT photoresistors. The normalized response time of the photoresistors from 0 to 1/e is around 0.5 s, as shown in FIG. 5. Around 800 nm the signal-to-noise ratio (SNR) was found to be 50-200, the noise-equivalent power (NEP) is 1-2 nanoWatt*Hertz^{-0.5} (nW*Hz^{-0.5}), and the detectivity is 0.5·10⁸-2·10⁸ cm*Hz^{0.5} W⁻¹.

FIG. 5 shows a typical normalized time response when the photoresistor is illuminated with a 900 nm wavelength. The rise time from 0 to 1/e (1 divided by Euler's number e) shown as a dashed line, is approximately 0.5 seconds.

The upward band bending near the photoresistor's surface, which influences the carrier's concentration over the surface may point to the ability of the surface to respond to the illumination. Cleaning the surface from physisorbed or chemisorbed organic contaminations may reduce the band bending and the total surface resistance, and may enhance the photoresistor's uniformity by removing random external contamination and reducing the samples's resistance variance.

The observed increase in response for 532 nm after the adsorption of organic molecules, as shown in FIGS. 2A-J, may be attributed to the process of creating new impurity levels at the surface. Both the NDT and CYS devices absorb light at a 532 nm wavelength in a manner that may be measured and detected, and do not absorb light at a 980 nm wavelength in any significant manner.

When the photoresistor was illuminated by a constant UV light to flatten the band bending, the potential barrier was lowered and the depletion layer became narrow. The resistance was lowered to the 200-300 ohm (Ω) range. At this mode the photoresistor were sensitive to VIS and NIR light.

The observed variance in spectral responses between the NDT and CYS photoresistors may be attributed to different positions of the impurity states energy levels and the surface trap concentrations. The peaks at around 600 nm and 800 nm may be explained as trap energies around 1.55 and 2.05 electron-volt (eV), and were identified as the known zinc impurities at 1.42 and 2.2 eV. The small shift in energy at approximately 0.15 eV and lack of observed peaks due to other known impurities may be attributed to the influence of the adsorbed molecules on the states. Adsorbed molecules may change the surface potential by creating local fields, where different molecules may have varying effects on the device's response, and which may be attributable to factors such as changes in the surface pinning, the density of states, the absorption cross-section, and the carrier intensity.

In the description and claims of the application, each of the words “comprise” “include” and “have”, and forms thereof, are not necessarily limited to members in a list with which the words may be associated. In addition, where there are inconsistencies between this application and any document incorporated by reference, it is hereby intended that the present application controls.

1. A photoresistor comprising:
a semiconductor substrate comprising a Group III-V material selected from the group consisting of: InAs, InP, InN, GaN, InSb, InAsP, InGaAs, GaAs, GaP, GaSb, AlP, MN, AlAs, AlSb, CdSeTe and ZnCdSe;
a layer of organic molecules that is disposed on at least a portion of the surface of the semiconductor substrate; and
two contacts in contact with the layer of organic molecules.

2. The photoresistor of claim 1, wherein the organic molecules comprise one or more groups selected from one or more thiols (—SH) and/or amines (—NH2).

3. The photoresistor of claim 2, wherein the organic molecules comprising one or more thiol groups are alkyls.

4. The photoresistor of claim 1, wherein the organic molecules are selected from the group consisting of: 1,9-nonanedithiol (NDT) and cysteamine (CYS).

5. The photoresistor of claim 1, wherein the semiconductor substrate is selected from the group consisting of: Gallium-Nitride, Gallium-Arsenic, Gallium Phosphide, and Aluminum Gallium Nitride.

6. The photoresistor of claim 1, wherein the two contacts form an interdigital pattern on the surface of the semiconductor substrate.

7. A method for detecting light, the method comprising
illuminating, with ultraviolet light, a photoresistor comprising a layer of organic molecules, wherein the illuminating light has an intensity that is insufficient for saturating the photoresistor;
measuring a response of the photoresistor to the illumination.

8. The method of claim 7, further comprising repeating the ullumination and measuring steps at a frequency that is less than or equal to 2 Hertz.

9. The method of claim 8, wherein the photoresistor comprises a semiconductor substrate selected from the group consisting of: Gallium-Nitride, Gallium-Arsenic, Gallium Phosphide, and Aluminum Gallium Nitride, and wherein the layer of organic molecules, are selected from the group consisting of: 1,9-nonanedithiol (NDT) and cysteamine (CYS).

10. A method for detecting light, the method comprising:
illuminating, with ultraviolet light, a photoresistor comprising a layer of organic molecules;
substantially saturating the photoresistor with the illuminating ultraviolet light;
illuminating the saturated photoresistor with light in the visible and/or near-infrared wavelengths; and
measuring a response of the photoresistor to the illumination of light in the visible and/or near-infrared wavelengths.

11. The method of claim 10, wherein the photoresistor comprises a semiconductor substrate selected from the group consisting of: Gallium-Nitride, Gallium-Arsenic, Gallium Phosphide, and Aluminum Gallium Nitride, and wherein the layer of organic molecules, are selected from the group consisting of: 1,9-nonanedithiol (NDT) and cysteamine (CYS).

12-20. (canceled)
